(19) United States
(12) Patent Application Publication
(10) Pub. No.: US 2026/0164677 A1
(43) Pub. Date: Jun. 11, 2026

(54) SEMICONDUCTOR DEVICE AND METHOD OF MANUFACTURING SEMICONDUCTOR DEVICE

(71) Applicant: SK hynix Inc., Icheon-si (KR)

(72) Inventor: Nam Kyun PARK, Icheon-si (KR)

(21) Appl. No.: 19/196,501

(22) Filed: May 1, 2025

(30) Foreign Application Priority Data
Dec. 11, 2024 (KR) 10-2024-0183846

(51) Int. Cl. H10B 63/00

(52) U.S. Cl. CPC H10B 63/80

(57) ABSTRACT

A semiconductor device includes first row lines extending in a first direction, first column lines located on the first row lines and extending in a second direction crossing the first direction, second column lines located on the first column lines, having a width greater than a width of the first column lines and extending in the second direction, second row lines located on the second column lines and extending in the first direction, first memory cells located between the first row lines and the first column lines, respectively, and second liner patterns surrounding a sidewall of the first memory cells and a sidewall of the first column lines adjacent in the first direction.

### CROSS-REFERENCE TO RELATED APPLICATION

This application claims priority under 35 U.S.C. § 119 to Korean Patent Application No. 10-2024-0183846 filed on Dec. 11, 2024, which is incorporated herein by reference in its entirety.

### BACKGROUND

### 1. Technical Field

The present disclosure relates to an electronic device and a method of manufacturing the electronic device, and more particularly, to a semiconductor device and a method of manufacturing the semiconductor device.

### 2. Related Art

The degree of integration of a semiconductor memory device is mainly determined by an area occupied by a unit memory cell. Recently, as improvements in the degree of integration of a semiconductor device in which a memory cell is formed as a single layer on a substrate reaches physical limits, a three-dimensional semiconductor device in which memory cells are stacked on a substrate is being proposed. In addition, various structures and manufacturing methods are being developed in order to improve reliability of the operation of semiconductor devices.

### SUMMARY

According to an embodiment of the present disclosure, a semiconductor device may include first row lines extending in a first direction; first column lines located over the first row lines and extending in a second direction crossing the first direction; second column lines located over the first column lines, the second column lines having a width greater than a width of the first column lines and extending in the second direction; second row lines located over the second column lines and extending in the first direction; first memory cells located between respective row lines and column lines of the first row lines and the first column lines; and second liner patterns disposed over sidewalls of the first memory cells and sidewalls of the first column lines that face the first direction.

According to an embodiment of the present disclosure, a method of manufacturing a semiconductor device may include forming first memory lines extending in a first direction; forming first gap-fill patterns between the first memory lines; forming a hard mask layer over the first memory lines; forming hard mask lines extending in a second direction crossing the first direction by etching the hard mask layer; forming first memory cells arranged in the first direction and the second direction by etching the first memory lines; forming second gap-fill patterns between adjacent memory cells of the first memory cells in the first direction; forming trenches by removing the hard mask lines; and forming a conductive material in the trenches.

### BRIEF DESCRIPTION OF THE DRAWINGS

FIGS. 1A to 1D are drawings illustrating a semiconductor device according to an embodiment of the present disclosure.

FIG. 2 is a drawing illustrating a semiconductor device according to an embodiment of the present disclosure.

FIG. 3 is a drawing illustrating a semiconductor device according to an embodiment of the present disclosure.

FIGS. 4A, 4B, 5A, 5B, 6A, 6B, 7A, 7B, 8A, 8B, 9A, 9B, 10A, 10B, 11A, and 11B are drawings illustrating a method of manufacturing a semiconductor device according to an embodiment of the present disclosure.

FIGS. 12A, 12B, 13A, 13B, 14A, 14B, 15A, 15B, 16A, and 16B are drawings illustrating a method of manufacturing a semiconductor device according to an embodiment of the present disclosure.

FIGS. 17A, 17B, 18A, 18B, 19A, 19B, 20A, 20B, 21A, 21B, 22A, and 22B are drawings illustrating a method of manufacturing a semiconductor device according to an embodiment of the present disclosure.

### DETAILED DESCRIPTION

Embodiments of the present disclosure relate to a semiconductor device and a method of manufacturing the semiconductor device having a stable structure and improved operating characteristics.

According to the present technology, a semiconductor device having a stable structure and improved reliability may be provided.

Hereinafter, embodiments of the present disclosure are described with reference to the accompanying drawings.

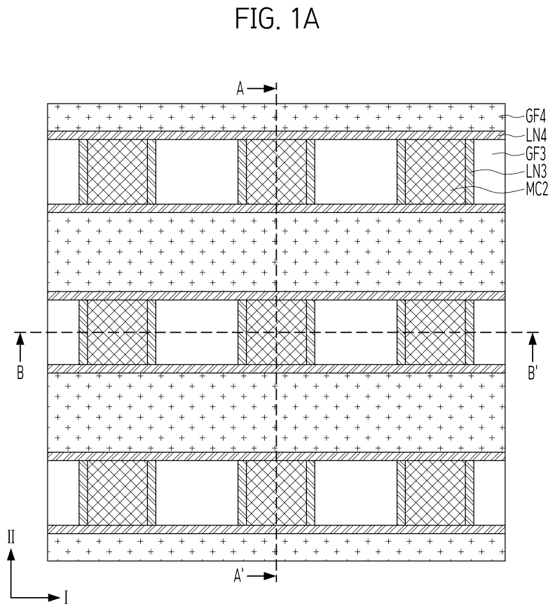

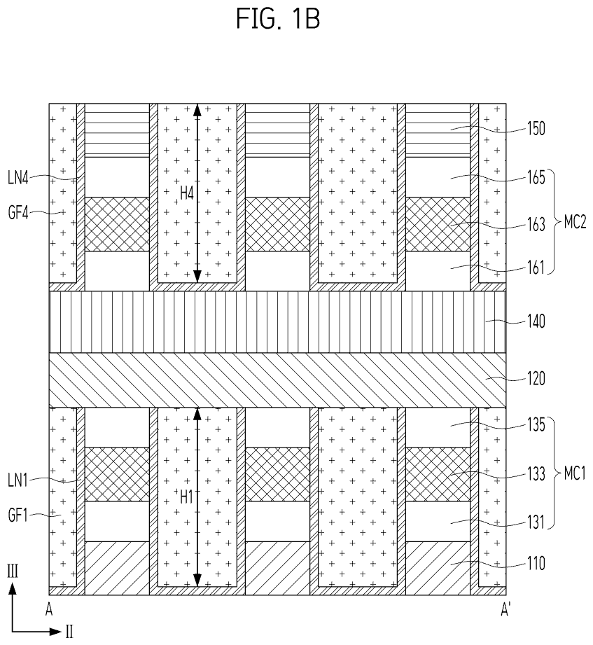

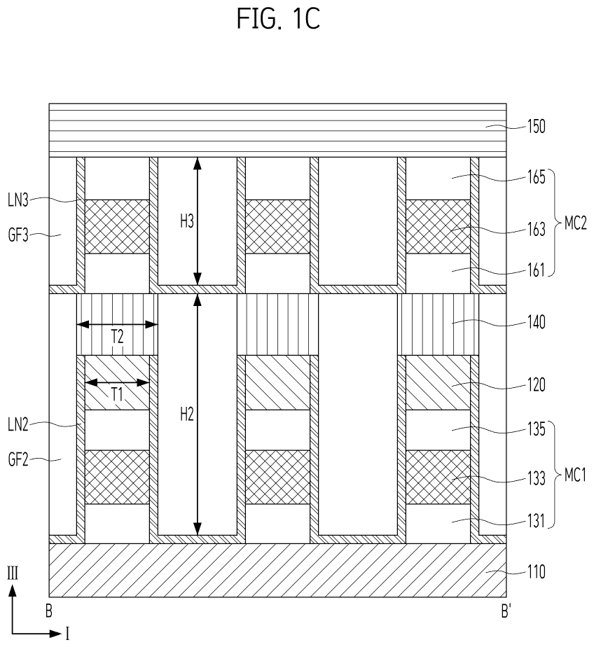

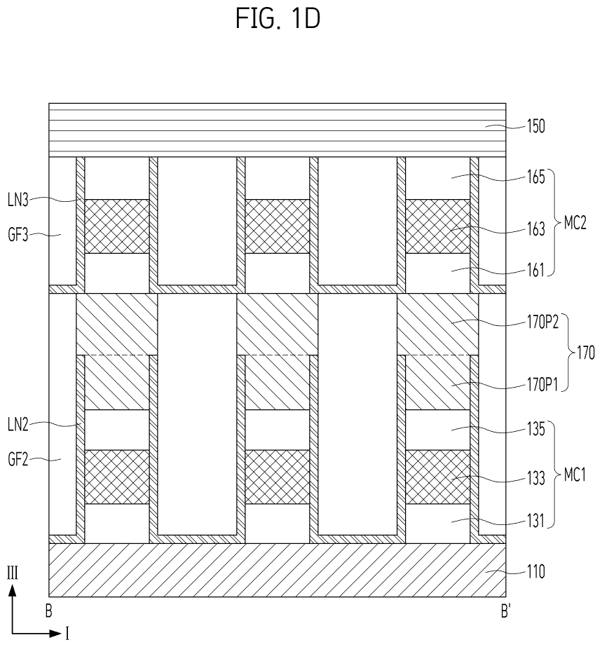

FIGS. 1A to 1D are drawings illustrating a semiconductor device according to an embodiment of the present disclosure. FIG. 1A is a plan view, FIG. 1B is a cross-sectional view taken along line A-A′ of FIG. 1A, and FIGS. 1C and 1D are cross-sectional views taken along line B-B′ of FIG. 1A.

Referring to FIGS. 1A to 1D, the semiconductor device may include first row lines 110, first column lines 120, second column lines 140, second row lines 150, first memory cells MC1, second memory cells MC2, first liner patterns LN1, second liner patterns LN2, third liner patterns LN3, fourth liner patterns LN4, first gap-fill patterns GF1, second gap-fill patterns GF2, third gap-fill patterns GF3, and fourth gap-fill patterns GF4.

The first row lines 110 may extend in a first direction I. The first column lines 120 may cross the first row lines 110 and may be located over the first row lines 110. The first column lines 120 may extend in a second direction II crossing the first direction I. For example, the first row lines 110 may be first word lines, and the first column lines 120 may be first bit lines. As another example, the first row lines 110 may be first bit lines, and the first column lines 120 may be first word lines. Here, the first row lines 110 and the first column lines 120 may include a conductive material such as tungsten.

The second column lines 140 may extend in the second direction II. The second column lines 140 may be located over the first column lines 120. The second column lines 140 may be electrically coupled to the first column lines 120. In some embodiments, as seen in FIG. 1D, the first column lines 120 and the second column lines 140 may be a substantially continuous structure without any discernable boundary between them. In this case, the first column lines 120 and the second column lines 140 may be common column lines 170. For example, referring to FIG. 1D, the common column lines 170 may include a first portion 170P1 and a second portion 170P2. Here, the first portion 170P1 may correspond to the first column lines 120, and the second portion 170P2 may correspond to the second column lines 140. In addition, the first portion 170P1 and the second portion 170P2 of the common column lines may be formed of the same material.

The second row lines 150 may extend in the first direction I. The second row lines 150 may be located over the second column lines 140. For example, the second column lines 140 may be second bit lines, and the second row lines 150 may be second word lines. As another example, the second column lines 140 may be second word lines, and the second row lines 150 may be second bit lines. Here, the second row lines 150 and the second column lines 140 may include a conductive material such as tungsten.

The first column lines 120 may have a first width T1 in the first direction. The second column lines 140 may have a second width T2 in the first direction. Here, the second width T2 may be substantially equal to or different from the first width T1. In some embodiments, the second width T2 may be greater than the first width T1.

The first memory cells MC1 may be located between respective row lines and column lines of the first row lines 110 and the first column lines 120. The second memory cells MC2 may be located between respective column lines and row lines of the second column lines 140 and the second row lines 150. In particular, first memory cells MC1 may located between first row lines 110 and first column lines 120 where the first row lines 110 cross the first column lines 120, and second memory cells MC2 may be located between the second column lines 140 and the second row lines 150 where the first column lines 120 cross the second column lines 140. Accordingly, the first memory cells MC1 may be coupled between first row lines 110 and first column lines 120, and second memory cells MC2 may be coupled between second column lines 140 and second row lines 150. Each of the first memory cells MC1 may include a first lower electrode pattern 131, a first variable resistance pattern 133, and a first upper electrode pattern 135. Each of the second memory cells MC2 may include a second lower electrode pattern 161, a second variable resistance pattern 163, and a second upper electrode pattern 165.

The first lower electrode pattern 131 may be located over the first row line 110. The first lower electrode pattern 131 may be a portion of the first row line 110 or may be electrically coupled to the first row line 110. The first upper electrode pattern 135 may be located over the first lower electrode pattern 131. The first upper electrode pattern 135 may be a portion of the first column line 120 or may be electrically coupled to the first column line 120. The first variable resistance pattern 133 may be located between the first lower electrode pattern 131 and the first upper electrode pattern 135.

The second lower electrode pattern 161 may be located over the second column line 140. The second lower electrode pattern 161 may be a portion of the second column line 140 or may be electrically coupled to the second column line 140. The second upper electrode pattern 165 may be located over the second lower electrode pattern 161. The second upper electrode pattern 165 may be a portion of the second low line 150 or may be electrically coupled to the second low line 150. The second variable resistance pattern 163 may be located between the second lower electrode pattern 161 and the second upper electrode pattern 165.

At least one of the first lower electrode pattern 131, the first upper electrode pattern 135, the second lower electrode pattern 161, and the second upper electrode pattern 165 may include polysilicon, tungsten (W), tungsten nitride (WNx), tungsten silicide (WSix), titanium (Ti), titanium nitride (TiNx), titanium silicon nitride (TiSiN), titanium aluminum nitride (TiAlN), tantalum (Ta), tantalum nitride (TaN), tantalum silicon nitride (TaSiN), tantalum aluminum nitride (TaAlN), carbon (C), silicon carbide (SiC), silicon carbon nitride (SiCN), copper (Cu), zinc (Zn), nickel (Ni), cobalt (Co), lead (Pb), platinum (Pt), molybdenum (Mo), ruthenium (Ru), or the like, and may include a combination thereof.

At least one of the first variable resistance pattern 133 and the second variable resistance pattern 163 may be used as a data storage and as a selection element. At least one of the first variable resistance pattern 133 and the second variable resistance pattern 163 may include a resistive material, and may have a characteristic of reversibly changing between different resistance states according to an applied voltage or current.

At least one of the first variable resistance pattern 133 and the second variable resistance pattern 163 may maintain an amorphous state during a program operation and may not change to a crystalline state after the program operation. In other words, a phase of at least one of the first variable resistance pattern 133 and the second variable resistance pattern 163 may not change after the program operation. For example, at least one of the first variable resistance pattern 133 and the second variable resistance pattern 163 may include a variable resistance material of which a resistance changes without a phase change, and may include a chalcogenide element. At least one of the first variable resistance pattern 133 and the second variable resistance pattern 163 may include germanium (Ge), antimony (Sb), arsenic (As), silicon (Si), indium (In), tin (Sn), gallium (Ga), or the like, or may include a combination thereof.

In some embodiments, in addition to or as an alternative to comprising a material that changes resistance without changing phase, at least one of the first variable resistance pattern 133 and the second variable resistance pattern 163 may include a phase change material and may include a chalcogenide. At least one of the first variable resistance pattern 133 and the second variable resistance pattern 163 may include a chalcogenide glass, a chalcogenide alloy, or the like. A phase of at least one of the first variable resistance pattern 133 and the second variable resistance pattern 163 may change according to the program operation. For example, at least one of the first variable resistance pattern 133 and the second variable resistance pattern 163 may have a low-resistant crystalline state by a set operation. In addition, at least one of the first variable resistance pattern 133 and the second variable resistance pattern 163 may have a high-resistant amorphous state by a reset operation. Therefore, at least one of the first variable resistance pattern 133 and the second variable resistance pattern 163 may store data in at least one of the first memory cell MC1 and the second memory cell MC2 by using a resistance difference according to a phase.

At least one of the first variable resistance pattern 133 and the second variable resistance pattern 163 may include a metal oxide which may be, for example, a transition metal oxide or a perovskite material. Therefore, data may be stored in the first and second memory cells MC1 and MC2 as an electrical path is created or removed in the variable resistance pattern 133 and the second variable resistance pattern 163.

At least one of the first variable resistance pattern 133 and the second variable resistance pattern 163 may have a magnetic tunnel junction (MTJ) structure, and may include a magnetization fixed layer, a magnetization free layer, and a tunnel barrier layer interposed therebetween. For example, the magnetization fixed layer the magnetization free layer may include a magnetic material, and the tunnel barrier layer may include an oxide of a metal such as magnesium (Mg), aluminum (Al), zinc (Zn), or titanium (Ti). Here, a magnetization direction of the magnetization free layer may be changed by spin torque of electrons in an applied current. Therefore, data may be stored in the first memory cell MC1 according to a change in the magnetization direction of the magnetization free layer for a magnetization direction of the magnetization fixed layer.

In addition, at least one of the first variable resistance pattern 133 and the second variable resistance pattern 163 may have a metal insulator metal (MIM) structure including a metal oxide. In this case, data may be stored in the first memory cell MC1 or the second memory cell MC2 by using a resistance change of a metal oxide that occurs by applying a short electric pulse.

In some embodiments, although not shown in the figures, the semiconductor device may further include a first intermediate electrode pattern, a second intermediate electrode pattern, a first switching pattern, and a second switching pattern. For example, the semiconductor device may include a structure in which the first lower electrode pattern 131, the first switching pattern, the first intermediate electrode pattern, the first variable resistance pattern 133, and the first upper electrode pattern 135 are sequentially stacked. In addition, the semiconductor device may include a structure in which the second lower electrode pattern 161, the second switching pattern, the second intermediate electrode pattern, the second variable resistance pattern 163, and the second upper electrode pattern 165 are sequentially stacked.

In this case, the first lower electrode pattern 131, the first switching pattern, and the first intermediate electrode pattern may configure a first selection element, and the second lower electrode pattern 161, the second switching pattern, and the second intermediate electrode pattern may configure a second selection element. The first and second selection elements may be a diode, a PNP diode, a transistor, a vertical transistor, a bipolar junction transistor (BJT), a metal insulator transition (MIT) element, a mixed ionic-electronic conduction (MIEC) element, an ovonic threshold switching element (OTS) element, and the like. For example, the first and second switching patterns may include a chalcogenide material.

In addition, the first intermediate electrode pattern, the first variable resistance pattern 133, and the first upper electrode pattern 135 may configure a first memory element, and the second intermediate electrode pattern, the second variable resistance pattern 163, and the second upper electrode pattern may configure a second memory element. The first and second memory elements and the first and second selection elements may share the first and second intermediate electrode patterns, respectively.

The first liner patterns LN1 may be disposed over sidewalls of the first memory cells MC1 that face the second direction II. The first liner patterns LN1 may cover a sidewall of the first memory cells MC1 and may extend over a sidewall of the first row lines 110. For example, each of the first liner patterns LN1 may extend along (e.g. over) and cover at least one sidewall of the first row line 110, the first lower electrode pattern 131, the first variable resistance pattern 133, and the first upper electrode pattern 135.

The second liner patterns LN2 may be disposed over sidewalls of the first memory cells MC1 that face the first direction I. The second liner patterns LN2 may cover a sidewall of the first memory cells MC1 and extend to a sidewall of the first column lines 120. For example, the second liner patterns LN2 may extend along and cover at least one sidewall of the first lower electrode pattern 131, the first variable resistance pattern 133, the first upper electrode pattern 135, and the first column line 120. In addition, upper surfaces of the second liner patterns LN2 may contact lower surfaces of the second column lines 140. This is because the second column lines 140 are formed at a location where a portion of the second liner patterns LN2 may be etched in a process of manufacturing the semiconductor device.

The third liner patterns LN3 may be disposed over sidewalls of the second memory cells MC2 that face the first direction I. For example, each of the third liner patterns LN3 may extend along and cover at least one sidewall of the second lower electrode pattern 161, the second variable resistance pattern 163, and the second upper electrode pattern 165.

The fourth liner patterns LN4 may be disposed over sidewalls of the second memory cells MC2 that face the second direction II. For example, each of the fourth liner patterns LN4 may extend along and cover at least one sidewall of the second lower electrode pattern 161, the second variable resistance pattern 163, the second upper electrode pattern 165, and the second row line 150.

The first liner patterns LN1 and the second liner patterns LN2 may protect the first memory cells MC1 in the process of manufacturing the semiconductor device. The third liner patterns LN3 and the fourth liner patterns LN4 may protect the second memory cells MC2 in the process of manufacturing the semiconductor device. At least one of the first liner patterns LN1, the second liner patterns LN2, the third liner patterns LN3, and the fourth liner patterns LN4 may include a nitride material.

The first gap-fill patterns GF1 may be located between adjacent memory cells of the first memory cells MC1 in the second direction II. The first liner patterns LN1 may be located between the first gap-fill patterns GF1 and the first memory cells MC1. The first gap-fill patterns GF1 may include an insulating material such as an oxide or nitride material.

The second gap-fill patterns GF2 may be located between adjacent memory cells of the first memory cells MC1 in the first direction I. The second liner patterns LN2 may be located between the second gap-fill patterns GF2 and the first memory cells MC1. Upper surfaces of the second gap-fill patterns GF2 may be located at substantially the same level as upper surfaces of the second column lines 140. The second gap-fill patterns GF2 may include an insulating material such as an oxide or nitride material.

The third gap-fill patterns GF3 may be located between adjacent memory cells of the second memory cells MC2 in the first direction I. The third liner patterns LN3 may be located between the third gap-fill patterns GF3 and the second memory cells MC2. The third gap-fill patterns GF3 may include an insulating material such as an oxide or nitride material.

The fourth gap-fill patterns GF4 may be located between adjacent memory cells of the second memory cells MC2 in the second direction II. The fourth liner patterns LN4 may be located between the fourth gap-fill patterns GF4 and the second memory cells MC2. The fourth gap-fill patterns GF4 may include an insulating material such as an oxide or nitride material.

The first gap-fill patterns GF1 may have a first height H1. The second gap-fill patterns GF2 may have a second height H2 different from the first height H1. For example, the second height H2 may be greater than the first height H1. This is because, in the process of manufacturing the semiconductor device, while the first gap-fill patterns GF1 are formed between the first row lines 110 and between the first memory cells MC1, the second gap-fill patterns GF2 are formed between the first memory cells MC1, between the first column lines 120, and between the second column lines 140.

The third gap-fill patterns GF3 may have a third height H3. The fourth gap-fill patterns GF4 may have a fourth height H4 different from the third height H3. For example, the fourth height H4 may be greater than the third height H3. This is because, in the process of manufacturing the semiconductor device, while the third gap-fill patterns GF3 are formed between the second memory cells MC2, the fourth gap-fill patterns GF4 are formed between the second memory cells MC2 and between the second row lines 150.

According to the structure described above, because the first memory cells MC1 and the second memory cells MC2 may be stacked, a degree of integration of the semiconductor device may be improved. Here, the first column lines 120 coupled to the first memory cells MC1 and the second column lines 140 coupled to the second memory cells MC2 may be electrically coupled to each other. In addition, the integration of the semiconductor device may be improved by forming additional layers of memory cells stacked above the second memory cells MC2 in a similar fashion.

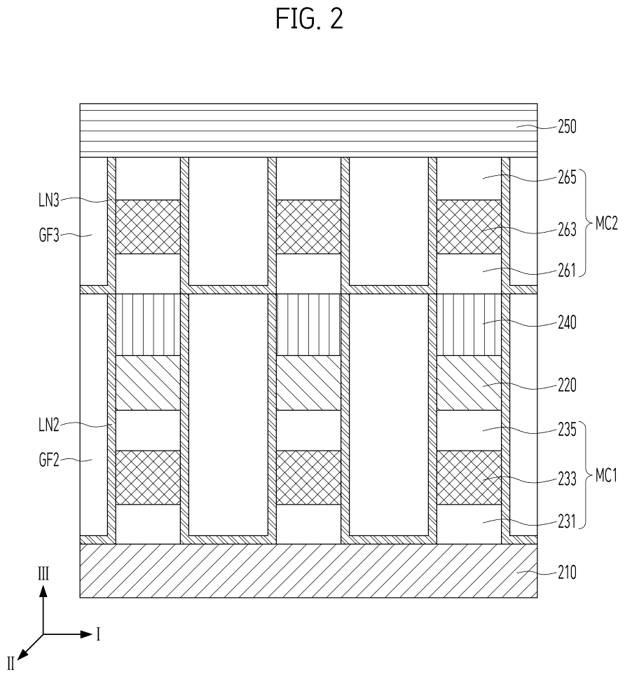

FIG. 2 is a drawing illustrating a semiconductor device according to an embodiment of the present disclosure. In the following description, some content that is redundant to the description above is omitted for clarity.

Referring to FIG. 2, the semiconductor device may include first row lines 210, first column lines 220, second column lines 240, second row lines 250, first memory cells MC1, second memory cells MC2, second liner patterns LN2, third liner patterns LN3, second gap-fill patterns GF2, and third gap-fill patterns GF3.

The first row lines 210 may extend in a first direction I. The first column lines 220 may cross the first row lines 210 and may be located over the first row lines 210. The first column lines 220 may extend in a second direction II crossing the first direction I.

The second column lines 240 may extend in the second direction II. The second column lines 240 may be located over the first column lines 220. The second column lines 240 may be electrically coupled to the first column lines 220. The first column lines 220 may have substantially the same width as the second column lines 240 In some embodiments, the first column lines 220 and the second column lines 240 may be a substantially continuous structure without any discernable boundary between them. In this case, the first column lines 220 and the second column lines 240 may be common column lines. The second row lines 250 may extend in the first direction I. The second row lines 250 may be located over the second column lines 240.

The first memory cells MC1 may be located between respective row lines and column lines of the first row lines 210 and first column lines 220. The second memory cells MC2 may be located between respective column lines and row lines of the second column lines 240 and second row lines 250. In particular, first memory cells MC1 may located between first row lines 210 and first column lines 220 where the first row lines 210 cross the first column lines 220, and second memory cells MC2 may be located between the second column lines 240 and the second row lines 250 where the first column lines 220 cross the second column lines 240. Accordingly, the first memory cells MC1 may be coupled between first row lines 210 and first column lines 220, and second memory cells MC2 may be coupled between second column lines 240 and second row lines 250. Each of the first memory cells MC1 may include a first lower electrode pattern 231, a first variable resistance pattern 233, and a first upper electrode pattern 235. Each of the second memory cells MC2 may include a second lower electrode pattern 261, a second variable resistance pattern 263, and a second upper electrode pattern 265.

The second liner patterns LN2 may be disposed over sidewalls of the first memory cells MC1 that face the first direction I. The second liner patterns LN2 may cover sidewalls of the first memory cells MC1 and may extend over a sidewall of the first column lines 220 and the second column lines 240. For example, the second liner patterns LN2 may extend along and cover at least one sidewall of the first lower electrode pattern 231, the first variable resistance pattern 233, the first upper electrode pattern 235, the first column line 220, and the second column line 240.

The third liner patterns LN3 may be disposed over sidewalls of the second memory cells MC2 that face the first direction I. For example, each of the third liner patterns LN3 may extend along and cover at least one sidewall of the second lower electrode pattern 261, the second variable resistance pattern 263, and the second upper electrode pattern 265.

An upper surface of the second liner patterns LN2 may be located at substantially the same level as an upper surface of the second column lines 240. The upper surfaces of the second liner patterns LN2 may contact lower surfaces of the third liner patterns LN3. This is because the second column lines 240 may be formed between the second liner patterns LN2 in a process of manufacturing the semiconductor device. Therefore, widths of the first column line 220 and the second column line 240 may be substantially the same.

In addition, the second liner patterns LN2 may protect the first memory cells MC1 in the process of manufacturing the semiconductor device, and the third liner patterns LN3 may protect the second memory cells MC2 in the process of manufacturing the semiconductor device. The second liner patterns LN2 and the third liner patterns LN3 may include a nitride material.

The second gap-fill patterns GF2 may be located between adjacent memory cells of the first memory cells MC1 in the first direction I. Upper surfaces of the second gap-fill patterns GF2 may be located at substantially the same level as upper surfaces of the second column lines 240. The upper surfaces of the second gap-fill patterns GF2 may be located at substantially the same level as the upper surfaces of the second liner patterns LN2. The second gap-fill patterns GF2 may include an insulating material such as an oxide or nitride material.

The third gap-fill patterns GF3 may be located between adjacent memory cells of the second memory cells MC2 in the first direction I. The third gap-fill patterns GF3 may include an insulating material such as an oxide or nitride material.

According to the structure described above, the second liner patterns LN2 may be disposed over sidewalls of the first memory cells MC1 and may extend over sidewalls of the first column lines 220 and the second column lines 240. In this case, in the process of manufacturing the semiconductor device, the width of the second column lines 240 may be formed to be substantially the same as the width of the first column lines 220 through the second liner patterns LN2.

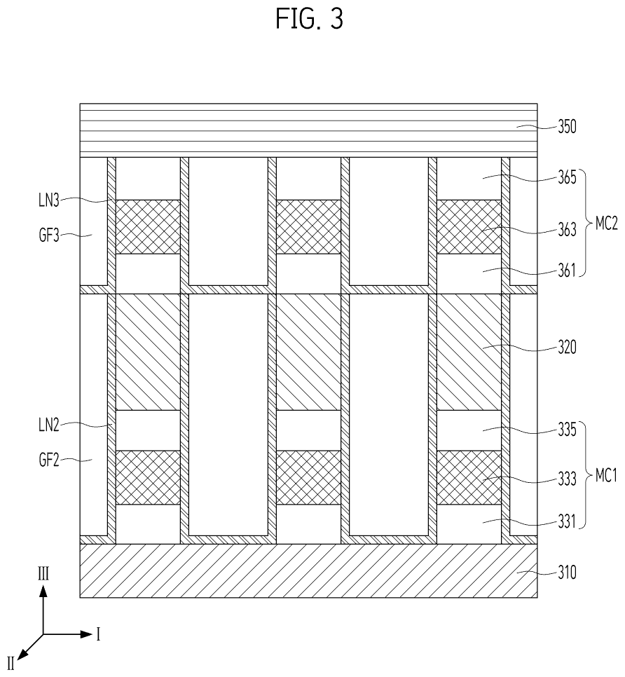

FIG. 3 is a drawing illustrating a semiconductor device according to an embodiment of the present disclosure. In the following description, some content that is redundant to the description above is omitted for clarity.

Referring to FIG. 3, the semiconductor device may include first row lines 310, common column lines 320, second row lines 350, first memory cells MC1, second memory cells MC2, second liner patterns LN2, third liner patterns LN3, second gap-fill patterns GF2, and third gap-fill patterns GF3.

The first row lines 310 and the second row lines 350 may extend in a first direction I. Here, the second row lines 350 may be located over the first row lines 310. The common column lines 320 may be located between respective row lines and column lines of the first row lines 310 and second row lines 350. The common column lines 320 may extend in a second direction II crossing the first direction I.

The first memory cells MC1 may be located between respective row lines and column lines of the first row lines 310 and the common column lines 320. The second memory cells MC2 may be located between respective column lines and row lines of the common column lines 320 and second row lines 350. In particular, first memory cells MC1 may located between first row lines 310 and first column lines 320 where the first row lines 310 cross the first column lines 320, and second memory cells MC2 may be located between the second column lines 340 and the second row lines 350 where the first column lines 320 cross the second column lines 340. Accordingly, the first memory cells MC1 may be coupled between first row lines 310 and first column lines 320, and second memory cells MC2 may be coupled between second column lines 340 and second row lines 350. Each of the first memory cells MC1 may include a first lower electrode pattern 331, a first variable resistance pattern 333, and a first upper electrode pattern 335. Each of the second memory cells MC2 may include a second lower electrode pattern 361, a second variable resistance pattern 363, and a second upper electrode pattern 365.

The second liner patterns LN2 may be disposed over sidewalls of the first memory cells MC1 that face the first direction I. The second liner patterns LN2 may cover sidewalls of the first memory cells MC1 and may extend over a sidewall of the common column lines 320. For example, the second liner patterns LN2 may extend along (e.g. over) and cover at least one sidewall of the first lower electrode pattern 331, the first variable resistance pattern 333, the first upper electrode pattern 335, and the common column line 320.

The third liner patterns LN3 may be disposed over sidewalls of the second memory cells MC2 that face the first direction I. For example, each of the third liner patterns LN3 may extend and cover at least one sidewall of along the second lower electrode pattern 361, the second variable resistance pattern 363, and the second upper electrode pattern 365.

An upper surface of the second liner patterns LN2 may be located at substantially the same level as an upper surface of the common column lines 320. The upper surfaces of the second liner patterns LN2 may contact lower surfaces of the third liner patterns LN3. This is because the common column lines 320 are formed in the second liner patterns LN2 in the process of manufacturing the semiconductor device.

In addition, the second liner patterns LN2 may protect the first memory cells MC1 in the process of manufacturing the semiconductor device, and the third liner patterns LN3 may protect the second memory cells MC2 in the process of manufacturing the semiconductor device. The second liner patterns LN2 and the third liner patterns LN3 may include a nitride material.

The second gap-fill patterns GF2 may be located between adjacent memory cells of the first memory cells MC1 in the first direction I. Upper surfaces of the second gap-fill patterns GF2 may be located at substantially the same level as upper surfaces of the common column lines 320. The upper surfaces of the second gap-fill patterns GF2 may be located at substantially the same level as the upper surfaces of the second liner patterns LN2. The second gap-fill patterns GF2 may include an insulating material such as an oxide or nitride material.

The third gap-fill patterns GF3 may be located between adjacent memory cells of the second memory cells MC2 in the first direction I. The third gap-fill patterns GF3 may include an insulating material such as an oxide or nitride material.

According to the structure described above, the first memory cells MC1 and the second memory cells MC2 may share the common column lines 320.

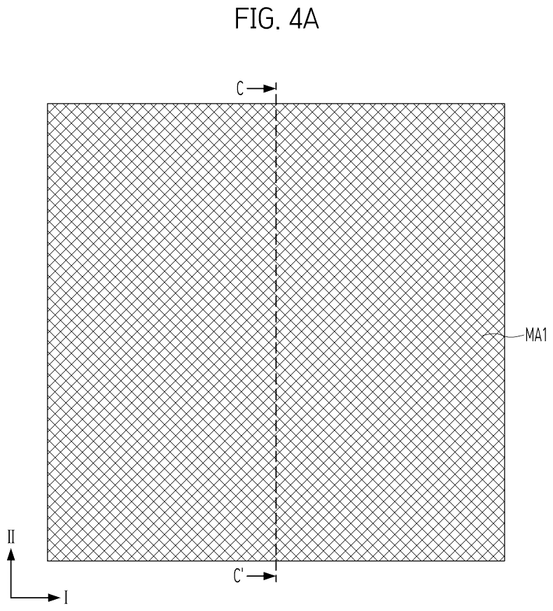

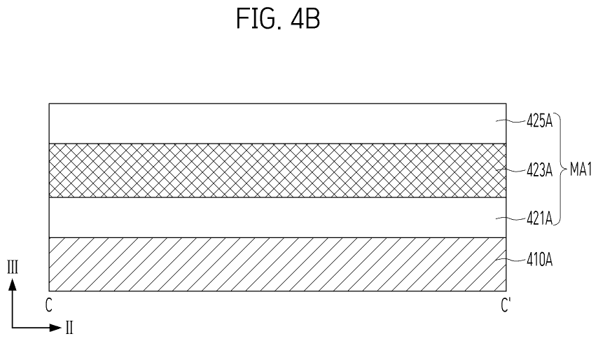

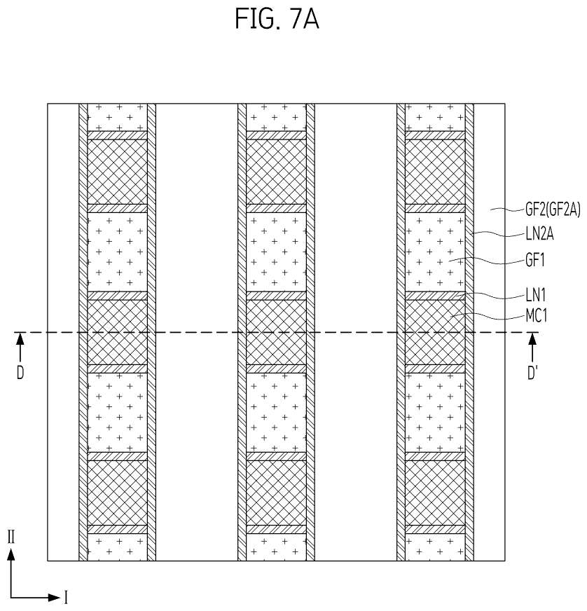

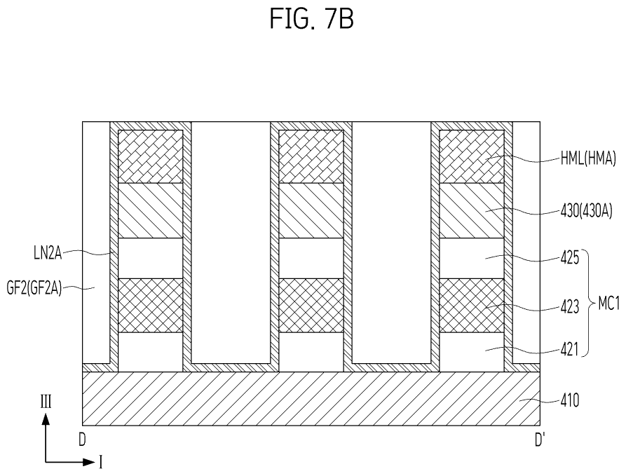

FIGS. 4A, 4B, 5A, 5B, 6A, 6B, 7A, 7B, 8A, 8B, 9A, 9B, 10A, 10B, 11A, and 11B are drawings illustrating a method of manufacturing a semiconductor device according to an embodiment of the present disclosure. FIGS. 4A, 5A, 6A, 7A, 8A, 9A, 10A, and 11A are plan views, FIGS. 4B, 5B, 6B, and 11B are cross-sectional views taken along line C-C′ of FIGS. 4A, 5A, 6A, and 11A, respectively, and FIGS. 7B, 8B, 9B, and 10B are cross-sectional views taken along line D-D′ of FIGS. 7A, 8A, 9A, and 10A, respectively. In the following description, some content that is redundant to the description above is omitted for clarity.

Referring to FIGS. 4A and 4B, a first memory layer MA1 may be formed over a first conductive layer 410A. For example, a first lower electrode layer 421A, a first variable resistance layer 423A, and a first upper electrode layer 425A may be sequentially stacked over the first conductive layer 410A to form the first memory layer MA1. Here, the first conductive layer 410A may include a conductive material such as tungsten.

In some embodiments, the first memory layer MA1 may further include a first switching layer and a first intermediate electrode layer. Here, the first switching layer may be formed between the first lower electrode layer 421A and the first intermediate electrode layer, and the first intermediate electrode layer may be formed between the first switching layer and the first variable resistance layer 423A.

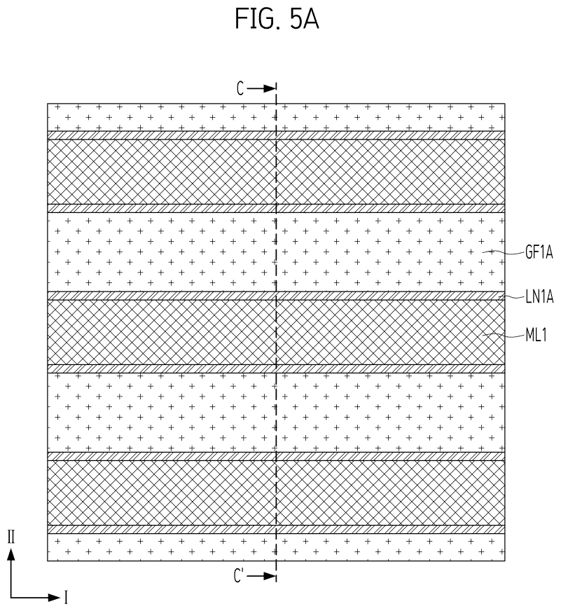

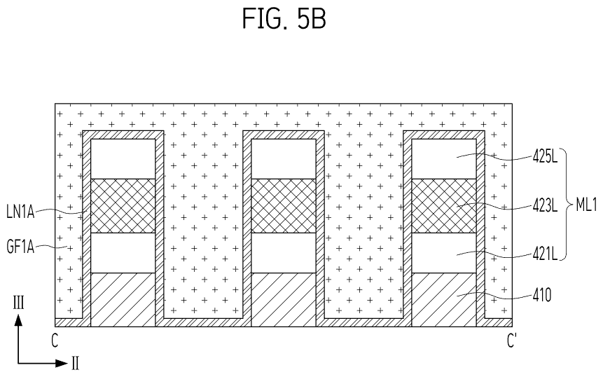

Referring to FIGS. 5A and 5B, first memory lines ML1 extending in a first direction I may be formed. For example, the first upper electrode layer 425A, the first variable resistance layer 423A, and the first lower electrode layer 421A may be sequentially etched to form the first memory lines ML1 including first upper electrode lines 425L, first variable resistance lines 423L, and first lower electrode lines 421L. In some embodiments, the first memory line ML1 may further include a first intermediate electrode line and a first switching line.

The first conductive layer 410A may be etched to form first row lines 410 extending in the first direction I. The first row lines 410 may be used as a word line or a bit line.

Subsequently, a first liner layer LN1A may be formed over the first memory lines ML1. For example, the first liner layer LN1A may be formed over a profile of the first memory lines ML1. Here, the first liner layer LN1A may include an insulating material such as a nitride material.

Subsequently, a first gap-fill layer GF1A may be formed over the first liner layer LN1A. For example, the first gap-fill layer GF1A may be formed to fill an area between the first memory lines ML1. Here, the first gap-fill layer GF1A may include a material having an etching selectivity with respect to the first liner layer LN1A. For example, the first gap-fill layer GF1A may include an insulating material such as an oxide material.

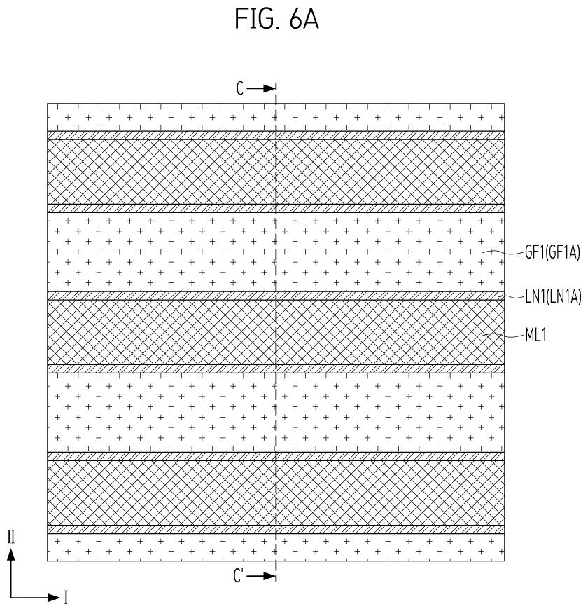

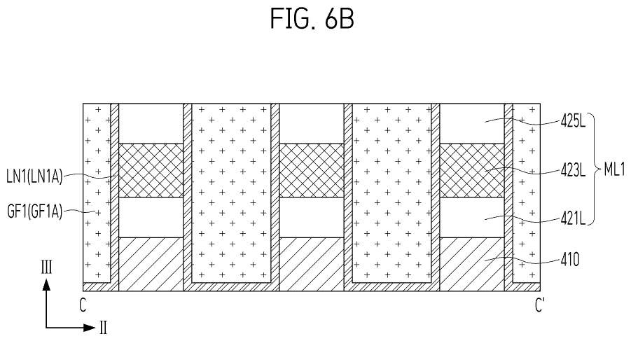

Referring to FIGS. 6A and 6B, first gap-fill patterns GF1 may be formed between the first memory lines ML1. For example, the first gap-fill layer GF1A may be planarized so that an upper surface of the first memory lines ML1 is exposed. In this process, the first gap-fill layer GF1A may be separated into the first gap-fill patterns GF1. In addition, the first liner layer LN1A may be separated into the first liner patterns LN1.

Referring to FIGS. 7A and 7B, a second conductive layer 430A may be formed over the first memory lines ML1. Subsequently, a hard mask layer HMA may be formed over the second conductive layer 430A. Here, the hard mask layer HMA may include a material having an etching selectivity with respect to the first gap-fill patterns GF1. For example, the hard mask layer HMA may include at least one of a nitride material and polysilicon.

Subsequently, first column lines 430 extending in a second direction II crossing the first direction I may be formed. For example, the second conductive layer 430A may be etched using the hard mask layer HMA as an etching barrier to form the first column lines 430. The second conductive layer 430A may be etched using an etching gas to form the first column lines 430. At this time, the second conductive layer 430A may be etched as much as desired by controlling an etching time or other parameters of the etching process. The etching gas may include a fluorine gas. For example, the etching gas may include at least one of CF₄ and SF₆. The first column lines 430 may be a first bit line or a first word line. In this process, the hard mask layer HMA may be separated into hard mask lines HML.

Subsequently, first memory cells MC1 may be formed. For example, the first memory lines ML1 may be etched using the hard mask lines HML as an etching barrier to form the first memory cells MC1. Here, an etching gas used to etch the first memory lines ML1 may be different from the etching gas used to etch the second conductive layer 430A. When the etching gas is the same, the first variable resistance lines 423L may be damaged in a process of etching the first memory lines ML1. Here, each of the first memory cells MC1 may include a first lower electrode pattern 421, a first variable resistance pattern 423, and a first upper electrode pattern 425. In some embodiments, the first memory cell MC1 may further include a first switching pattern and a first intermediate electrode pattern.

Subsequently, a second liner layer LN2A may be formed over the first memory cells MC1. For example, the second liner layer LN2A may be formed over a profile of the first memory cells MC1 including areas between the first memory cells MC1. Here, the second liner layer LN2A may include substantially the same material as the first liner layer LN1A. For example, the second liner layer LN2A may include an insulating material such as a nitride material.

Subsequently, a second gap-fill layer GF2A may be formed over the second liner layer LN2A. For example, the second gap-fill layer GF2A may be formed to fill an area between the first memory cells MC1. Here, the second gap-fill layer GF2A may include a material having an etching selectivity with respect to the second liner layer LN2A. For example, the second gap-fill layer GF2A may include an insulating material such as an oxide material.

Subsequently, second gap-fill patterns GF2 may be formed between the first memory cells MC1. For example, the second gap-fill layer GF2A may be planarized so that an upper surface of the second liner layer LN2A is exposed. In this process, the second gap-fill layer GF2A may be separated into the second gap-fill patterns GF2.

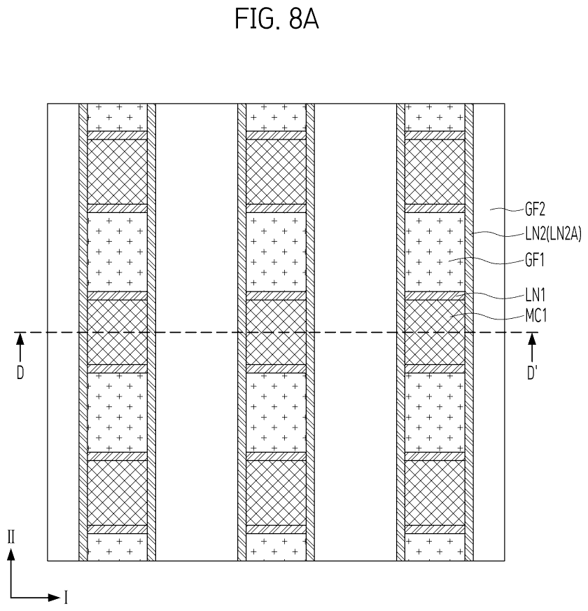

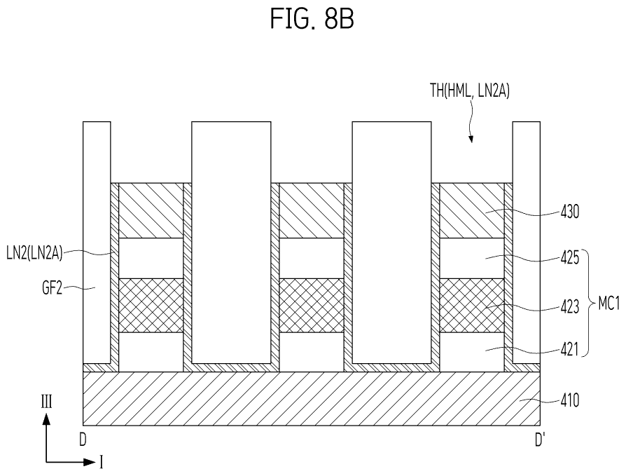

Referring to FIGS. 8A and 8B, trenches TH may be formed by removing the hard mask lines HML so that the first column lines 430 are exposed. For example, the trenches TH may be formed by removing the second liner layers LN2A and the hard mask lines HML so that the first column lines 430 are exposed.

The second gap-fill patterns GF2 may include a material having an etching selectivity with respect to the second liner layer LN2A and the hard mask lines HML. For example, the second gap-fill patterns GF2 may include an oxide material, and the second liner layer LN2A and the hard mask lines HML may include a nitride material. In this case, the trenches TH may be formed by selectively removing the second liner layer LN2A and the hard mask lines HML by using the second gap-fill patterns GF2 as an etching barrier. The etching process may be a dry or wet process as known in the art. In this process, the second liner layer LN2A may be separated into the second liner patterns LN2.

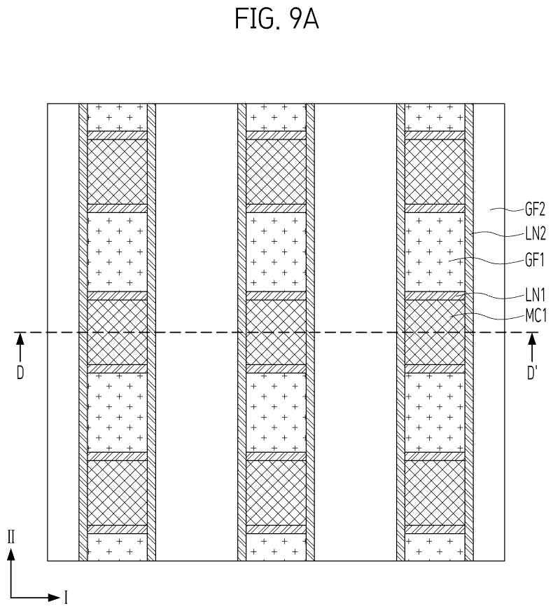

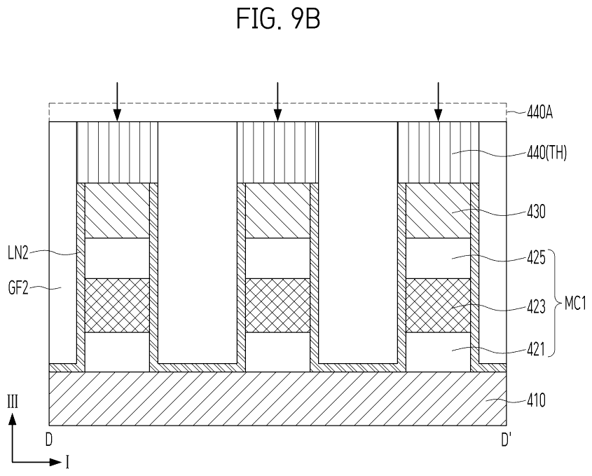

Referring to FIGS. 9A and 9B, a conductive material may be formed in the trenches TH to form second column lines 440. Here, the conductive material may include tungsten or the like. First, a third conductive layer 440A may be formed by depositing a conductive material to fill the trenches TH. Subsequently, the third conductive layer 440A may be planarized so that the second gap-fill patterns GF2 are exposed to form the second column lines 440 in the trenches TH. Here, the second column lines 440 may be electrically coupled to the first column lines 430. In some embodiments, the second column lines 440 and the first column lines 430 may be a substantially continuous structure without any discernable boundary between them. The second column line 440 may be a second bit line or a second word line.

When the second column lines 440 are formed using an etching process, a fluorine gas may be used. In this case, the first memory cells MC1 formed under the second column lines 440 may be damaged. Accordingly, in an embodiment of the present disclosure, the second column lines 440 may be formed using a damascene process instead of an etching process. In other words, because the second column lines 440 are formed by a process that does not use an etching gas according to an embodiment of the present disclosure, damage to the first memory cells MC1 may be prevented or reduced when forming the second column lines 440.

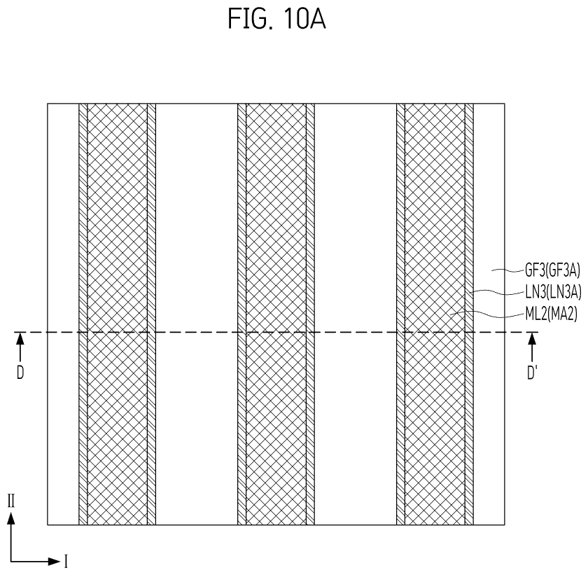

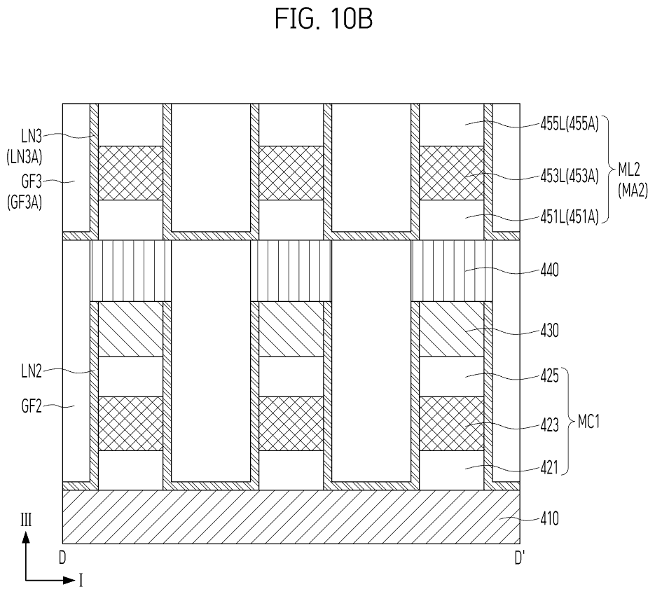

Referring to FIGS. 10A and 10B, second memory lines ML2 extending in the second direction II may be formed over the second column lines 440. First, a second memory layer MA2 may be formed over the second column lines 440. Here, the second memory layer MA2 may include a second lower electrode layer 451A, a second variable resistance layer 453A, and a second upper electrode layer 455A. In some embodiments, the second memory layer MA2 may further include a second intermediate electrode layer and a second switching layer. Subsequently, the second memory layer MA2 may be etched to form the second memory lines ML2. Here, the second memory lines ML2 may include second lower electrode lines 451L, second variable resistance lines 453L, and second upper electrode lines 455L. In some embodiments, the second memory lines ML2 may further include second intermediate electrode lines and second switching lines.

Because the second column lines 440 located under the second memory lines ML2 are first formed using a damascene process, it is not necessary to perform a process of forming the second column lines 440. In this case, because an etching gas for forming the second column lines 440 is not required to be used, damage to the second memory lines ML2 may be prevented.

Subsequently, a third liner layer LN3A may be formed over the second memory lines ML2. Subsequently, a third gap-fill layer GF3A may be formed over the third liner layer LN3A. Here, the third liner layer LN3A may include an insulating material such as a nitride material, and the third gap-fill layer GF3A may include an insulating material such as an oxide material.

Subsequently, the third gap-fill layer GF3A may be planarized so that an upper surface of the second memory lines ML2 is exposed. In this process, the third gap-fill layer GF3A may be separated into third gap-fill patterns GF3. In addition, the third liner layer LN3A may be separated into third liner patterns LN3.

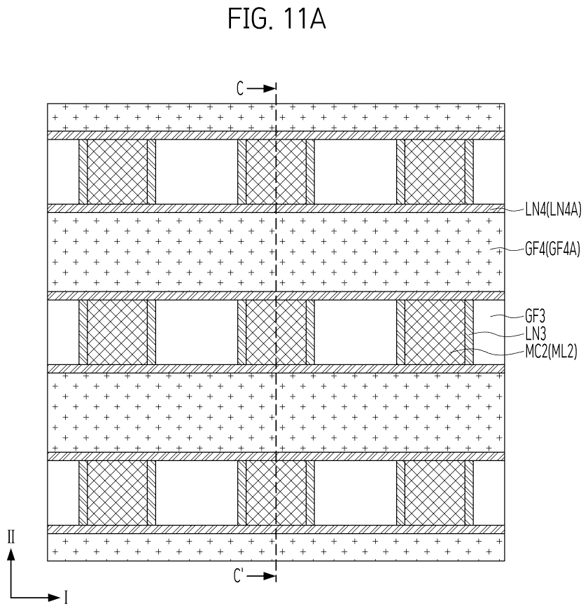

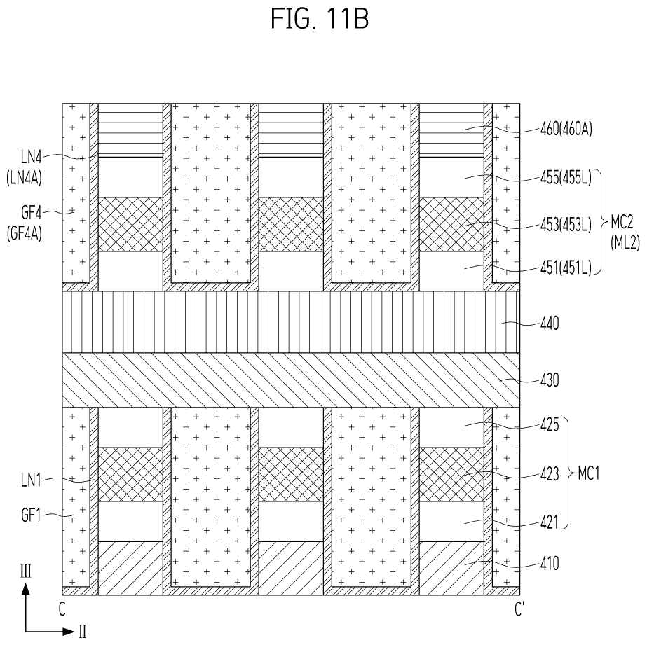

Referring to FIGS. 11A and 11B, second row lines 460 extending in the first direction I may be formed. First, a fourth conductive layer 460A may be formed over the second memory lines ML2. Subsequently, the fourth conductive layer 460A may be etched to form the second row lines 460.

Subsequently, the second memory lines ML2 may be etched to form second memory cells MC2. Here, each of the second memory cells MC2 may include a second lower electrode pattern 451, a second variable resistance pattern 453, and a second upper electrode pattern 455. In some embodiments, the second memory cell MC2 may further include a second intermediate electrode pattern and a second switching pattern.

Subsequently, a fourth liner layer LN4A may be formed over the second memory cells MC2. Subsequently, a fourth gap-fill layer GF4A may be formed over the fourth liner layer LN4A. Here, the fourth liner layer LN4A may include an insulating material such as a nitride material, and the fourth gap-fill layer GF4A may include an insulating material such as an oxide material.

Subsequently, the fourth gap-fill layer GF4A may be planarized so that the second row lines 460 are exposed. In this process, the fourth gap-fill layer GF4A may be separated into fourth gap-fill patterns GF4. In addition, the fourth liner layer LN4A may be separated into fourth liner patterns LN4.

According to the manufacturing method described above, the second liner layer LN2A and the hard mask lines HML may be selectively removed to form the trenches TH. Subsequently, the second column lines 440 may be formed in the trenches TH using a damascene process. In this case, because an etching gas may not be used, damage to the first memory cells MC1 formed under the second column lines 440 and the second memory cells MC2 formed over the second column lines 440 may be prevented.

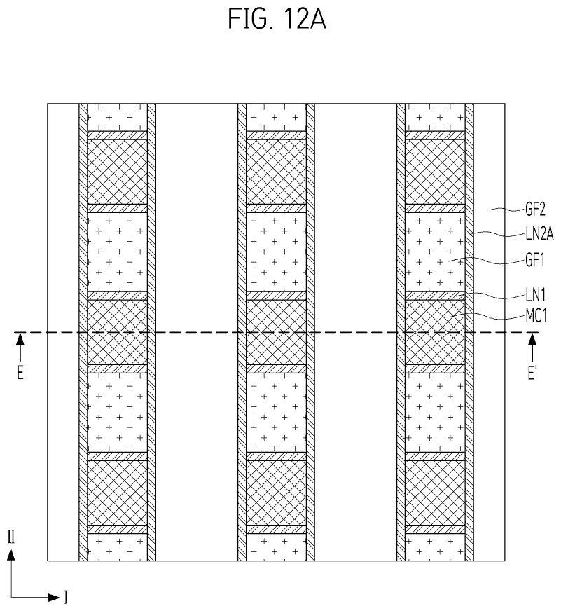

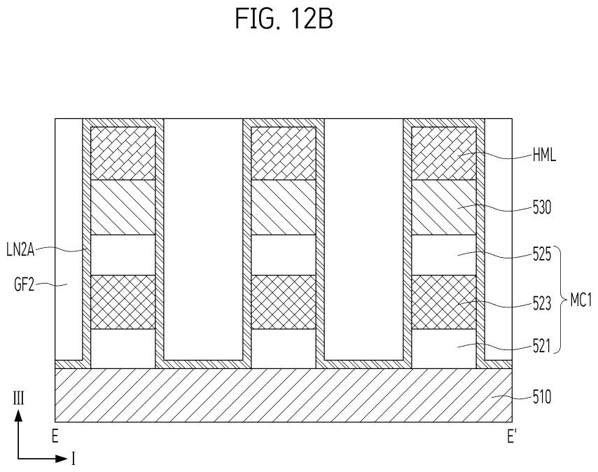

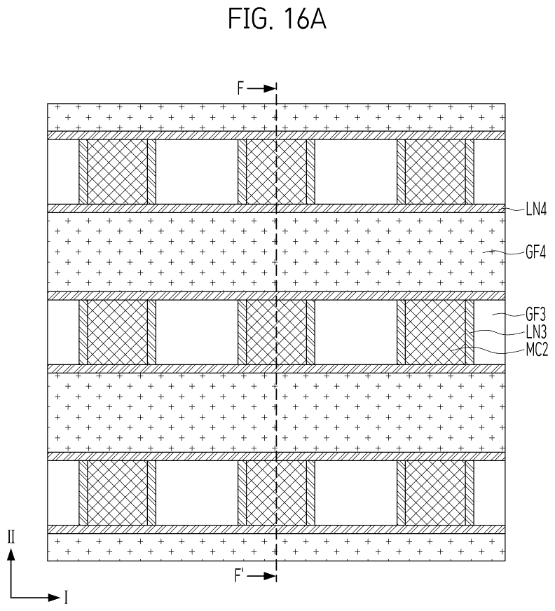

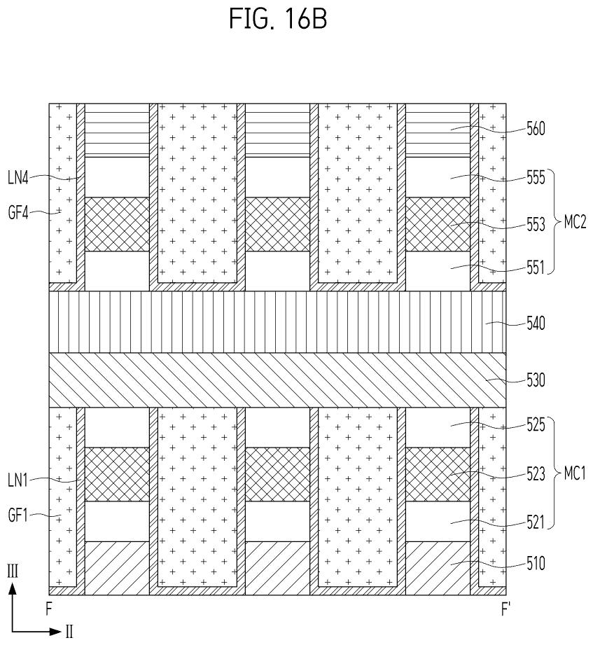

FIGS. 12A, 12B, 13A, 13B, 14A, 14B, 15A, 15B, 16A, and 16B are drawings illustrating a method of manufacturing a semiconductor device according to an embodiment of the present disclosure. FIGS. 12A, 13A, 14A, 15A, and 16A are plan views, FIGS. 12B, 13B, 14B, and 15B are cross-sectional views taken along line E-E′ of FIGS. 12A, 13A, 14A, and 15A, respectively, and FIG. 16B is a cross-sectional view taken along line F-F′ of FIG. 16A. In the following description, some content that is redundant to the description above is omitted for clarity.

Referring to FIGS. 12A and 12B, first row lines 510, first memory cells MC1, first column lines 530, hard mask lines HML, first liner patterns LN1, second liner layer LN2A, first gap-fill patterns GF1, and second gap-fill patterns GF2 may be formed using processes which are the same or similar to those of the method of forming the first row lines 410, the first memory cells MC1, the first column lines 430, the hard mask lines HML, the first liner patterns LN1, the second liner layer LN2A, the first gap-fill patterns GF1, and the second gap-fill patterns GF2 described with respect to FIGS. 4A to 7B. Here, the first memory cell MC1 may include a first lower electrode pattern 521, a first variable resistance pattern 523, and a first upper electrode pattern 525.

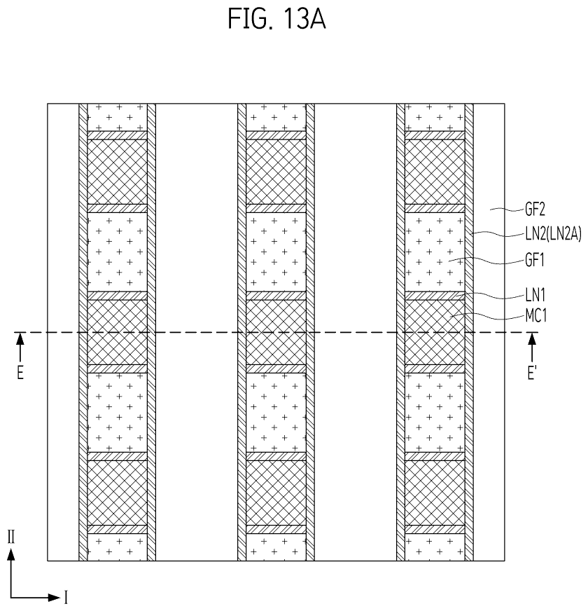

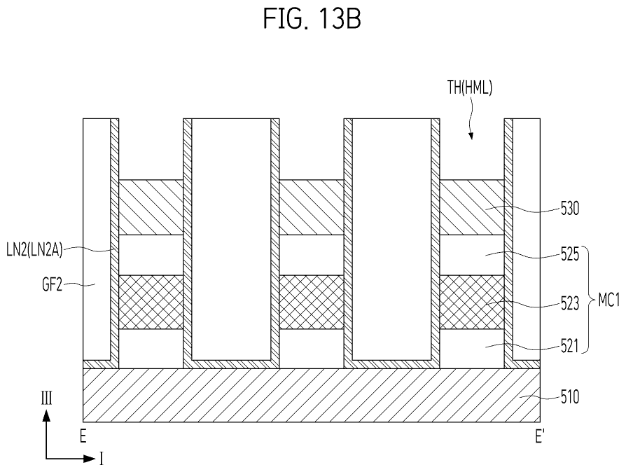

Referring to FIGS. 13A and 13B, second liner patterns LN2 may be formed by planarizing the second liner layer LN2A. Here, the second liner patterns LN2 may be formed when forming the second gap-fill patterns GF2. For example, when forming the second gap-fill patterns GF2 by planarizing the second gap-fill layer, the second liner layer LN2A may be separated into the second liner patterns LN2. In other words, a planarization process may be performed until the hard mask lines HML are exposed.

Subsequently, the hard mask lines HML may be removed so that the first column lines 530 are exposed to form trenches TH. For example, the hard mask lines HML may be selectively removed so that the first column lines 530 are exposed to form the trenches TH.

The second liner patterns LN2 may include a material having an etching selectivity with respect to the hard mask lines HML. For example, the second liner patterns LN2 may include a nitride material, and the hard mask lines HML may include polysilicon. In this case, the trenches TH may be formed by selectively removing the hard mask lines HML using the second liner patterns LN2 as an etching barrier.

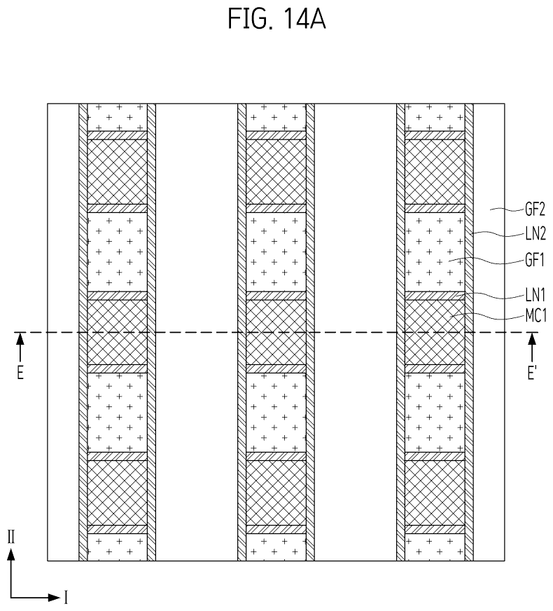

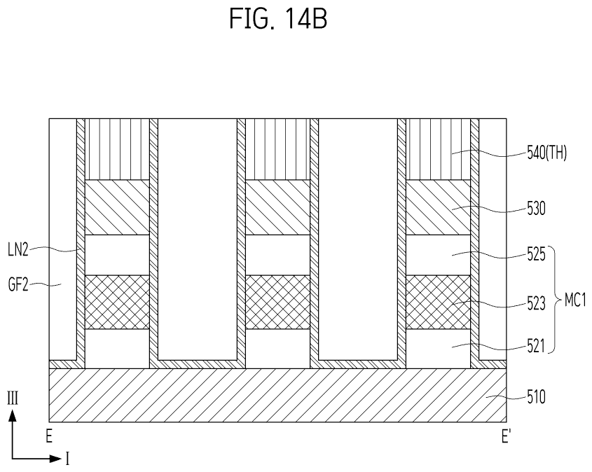

Referring to FIGS. 14A and 14B, a conductive material may be formed in the trenches TH to form second column lines 540. For example, the second column lines 540 may be formed using processes that are the same or similar to those of the method of forming the second column lines 440 in FIGS. 9A and 9B. A conductive material such as tungsten may be deposited to fill the trenches TH, and the conductive material may be planarized so that the second gap-fill patterns GF2 are exposed to form the second column lines 540 in the trenches TH. Here, the second column lines 540 may be electrically coupled to the first column lines 530. As a result of these processes, the second column lines 540 may be formed with substantially the same width as the first column lines 530.

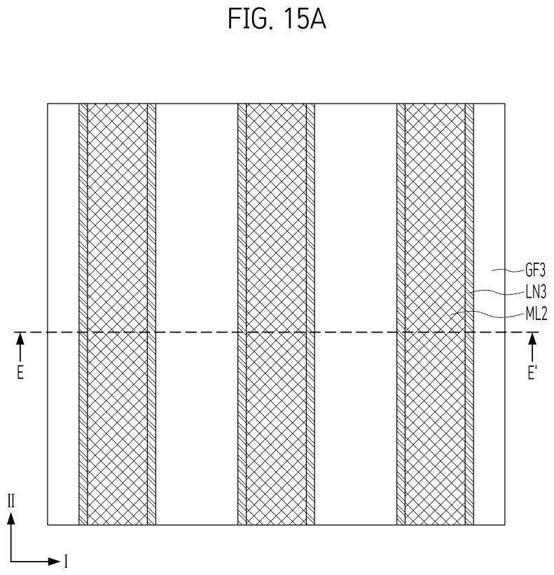

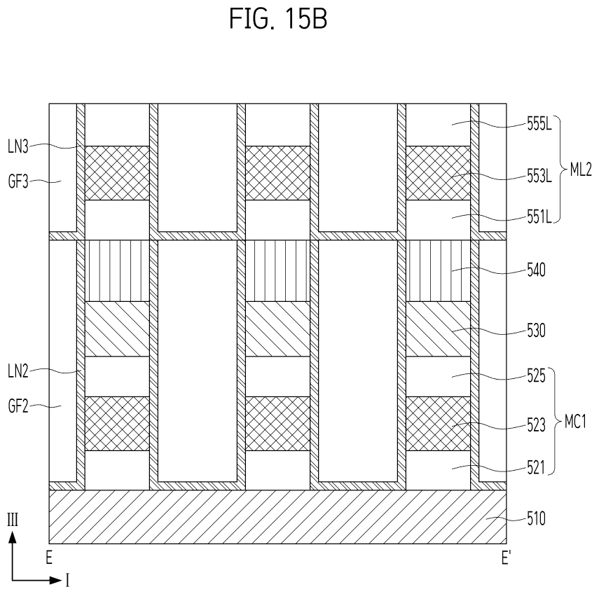

Referring to FIGS. 15A and 15B, second memory lines ML2, third gap-fill patterns GF3, and third liner patterns LN3 may be formed using processes which are the same or similar to those of the method of forming the second memory lines ML2, the third gap-fill patterns GF3, and the third liner patterns LN3 of FIGS. 10A and 10B. Here, the second memory lines ML2 may include second lower electrode lines 551L, second variable resistance lines 553L, and second upper electrode lines 555L.

Referring to FIGS. 16A and 16B, second memory cells MC2, second row lines 560, fourth gap-fill patterns GF4, and fourth liner patterns LN4 may be formed using processes which are the same or similar to those of the method of forming the second memory cells MC2, the second row lines 460, the fourth gap-fill patterns GF4, and the fourth liner patterns LN4 of FIGS. 11A and 11B. Here, the second memory cell MC2 may include a second lower electrode pattern 551, a second variable resistance pattern 553, and a second upper electrode pattern 555.

According to the manufacturing method described above, the hard mask lines HML formed in the second liner patterns LN2 may be selectively removed to form the trenches TH, and the second column lines 540 may be formed in the trenches TH using a damascene process. In this case, the second column lines 540 may be formed with substantially the same width as the first column lines 530.

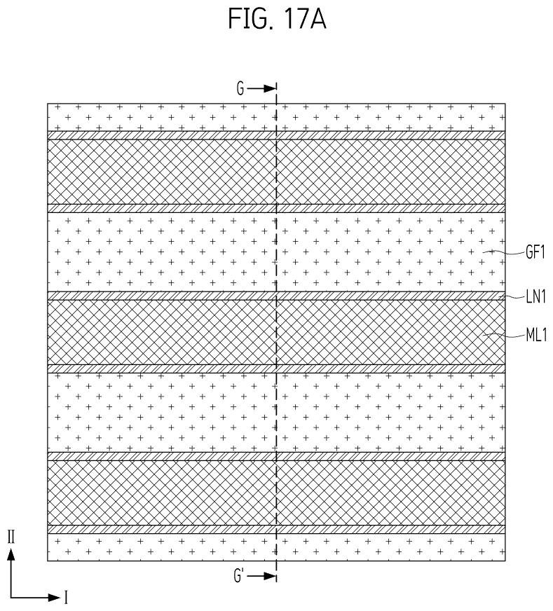

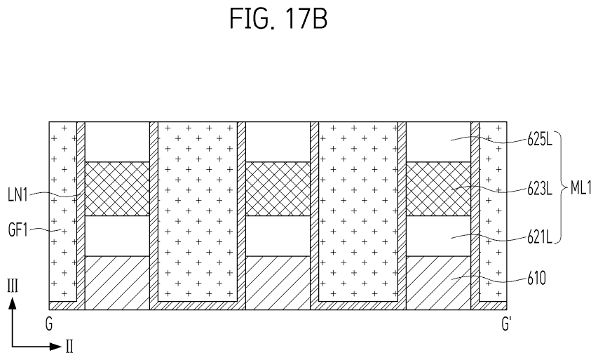

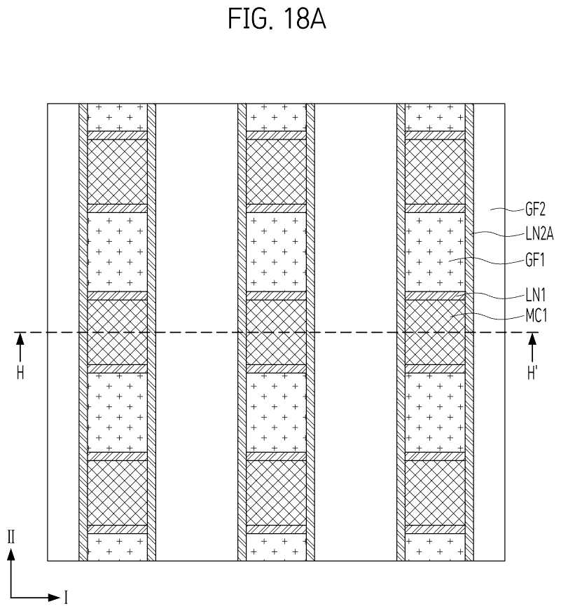

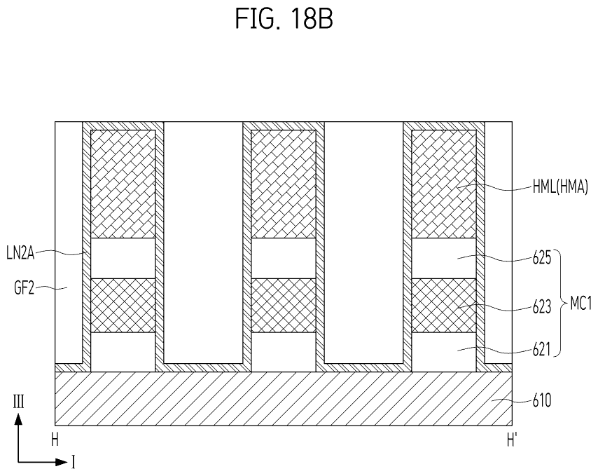

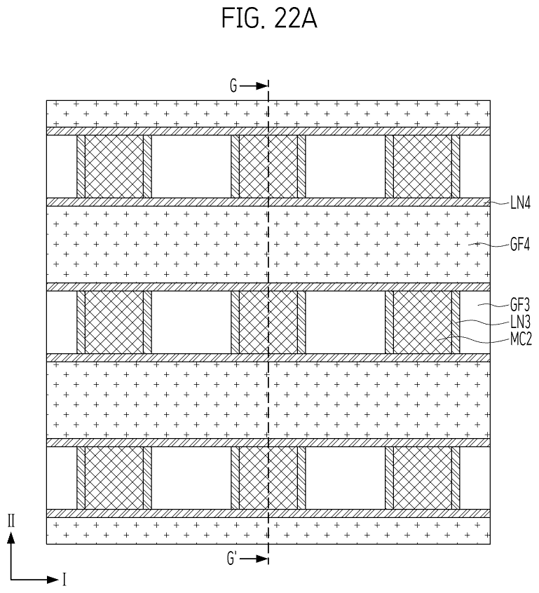

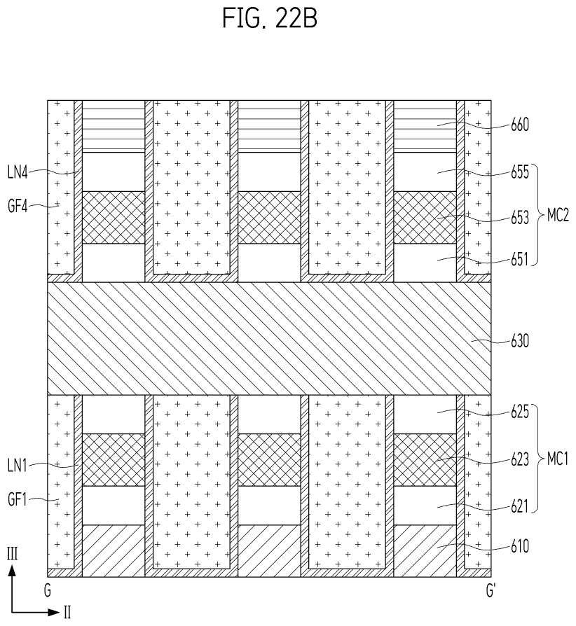

FIGS. 17A, 17B, 18A, 18B, 19A, 19B, 20A, 20B, 21A, 21B, 22A, and 22B are drawings illustrating a method of manufacturing a semiconductor device according to an embodiment of the present disclosure. FIGS. 17A, 18B, 19A, 20A, 21A, and 22A are plan views, FIGS. 17B and 22B are cross-sectional views taken along line G-G′ of FIGS. 17A and 22A, respectively, and FIGS. 18B, 19B, 20B, and 21B are cross-sectional views taken along line H-H′ of FIGS. 18A, 19A, 20A, and 21A, respectively. In the following description, some content that is redundant to the description above is omitted for clarity.

Referring to FIGS. 17A and 17A, first row lines 610, first memory lines ML1, first liner patterns LN1, and first gap-fill patterns GF1 may be formed using processes which are the same or similar to those of the method of forming the first row lines 410, the first memory lines ML1, the first liner patterns LN1, and the first gap-fill patterns GF1 through FIGS. 4A to 6B. Here, the first memory lines ML1 may include first lower electrode lines 621L, first variable resistance lines 623L, and first upper electrode lines 625L.

Referring to FIGS. 18A and 18B, a hard mask layer HMA may be formed over the first memory lines ML1. Here, the hard mask layer HMA may include at least one of polysilicon and a nitride material.

Subsequently, the first memory lines ML1 may be etched using the hard mask layer HMA as an etching barrier to form first memory cells MC1. Here, each of the first memory cells MC1 may include a first lower electrode pattern 621, a first variable resistance pattern 623, and a first upper electrode pattern 625.

Subsequently, a second liner layer LN2A may be formed over the first memory cells MC1. Subsequently, a second gap-fill layer may be formed over the second liner layer LN2A. Subsequently, second gap-fill patterns GF2 may be formed between the first memory cells MC1. For example, the second gap-fill layer may be planarized so that an upper surface of the second liner layer LN2A is exposed. In this process, the second gap-fill layer may be separated into the second gap-fill patterns GF2.

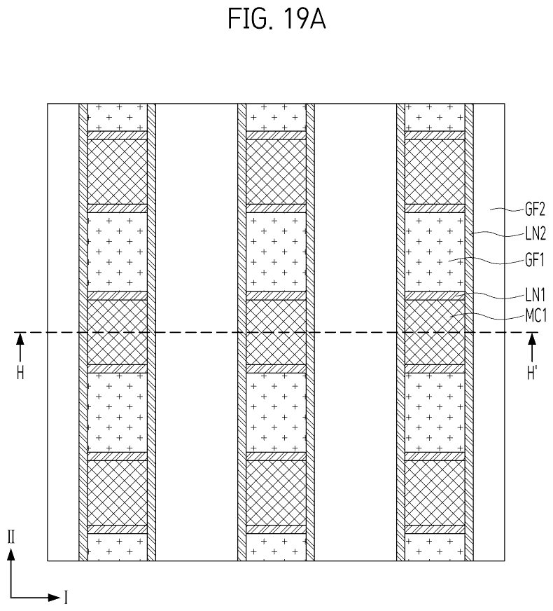

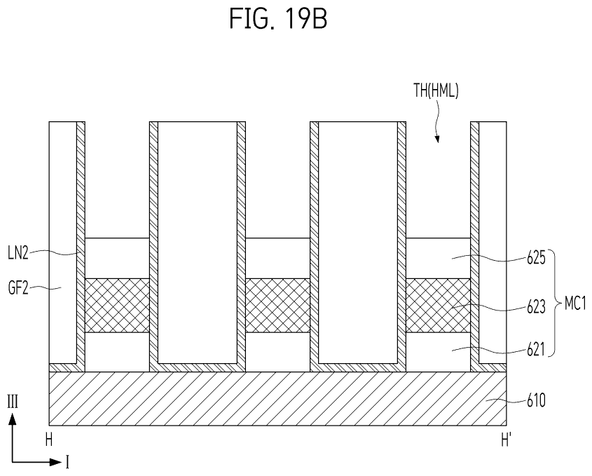

Referring to FIGS. 19A and 19B, the second liner layer LN2A may be planarized to form second liner patterns LN2. Here, the second liner patterns LN2 may be formed when forming the second gap-fill patterns GF2. For example, when forming the second gap-fill patterns GF2 by planarizing the second gap-fill layer, the second liner layer LN2A may be separated into the second liner patterns LN2. Accordingly, a planarization process may be performed until the hard mask lines HML are exposed.

Subsequently, the hard mask lines HML may be removed so that the first memory cells MC1 are exposed to form trenches TH. For example, the hard mask lines HML may be selectively removed so that the first memory cells MC1 are exposed to form the trenches TH.

The second liner patterns LN2 may include a material having an etching selectivity with respect to the hard mask lines HML. For example, the second liner patterns LN2 may include a nitride material, and the hard mask lines HML may include polysilicon. In this case, the hard mask lines HML may be selectively removed using the second liner patterns LN2 as an etching barrier to form the trenches TH.

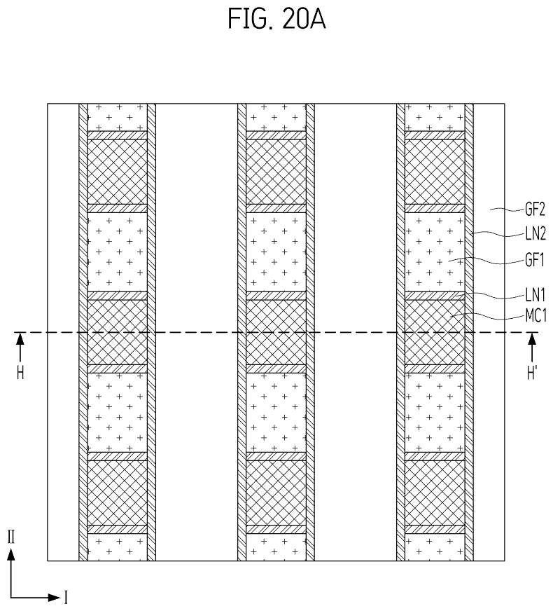

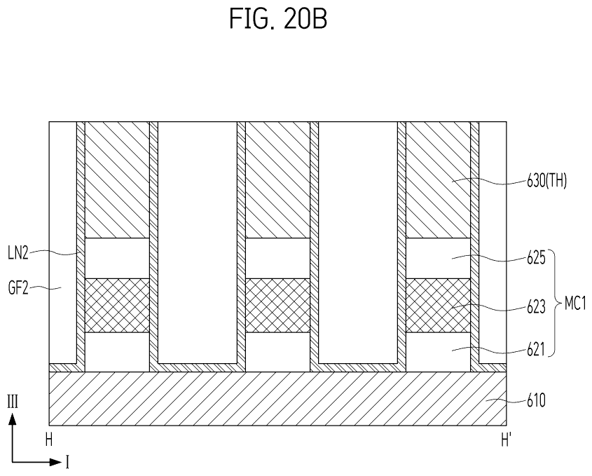

Referring to FIGS. 20A and 20B, a conductive material may be formed in the trenches TH to form common column lines 630. For example, a conductive material such as tungsten may be deposited to fill the trenches TH, and the conductive material may be planarized so that the second gap-fill patterns GF2 are exposed to form the common column lines 630 in the trenches TH. Here, the common column lines 630 may be shared with the first memory cells MC1 and second memory cells MC2 formed in a subsequent process.

In some embodiments, when the hard mask lines HML include a nitride material, the second liner patterns LN2 and the hard mask lines HML may be simultaneously removed to form the trenches TH. For example, the hard mask lines HML and the second liner patterns LN2 may be removed so that an upper surface of the second liner patterns LN2 and an upper surface of the first upper electrode 625 of the first memory cell MC1 become substantially at the same level to form the trenches TH. Thereafter, when forming the common column lines 630 in the trenches TH, a width of the common column lines 630 may be formed to be greater than a width of the first upper electrodes 625.

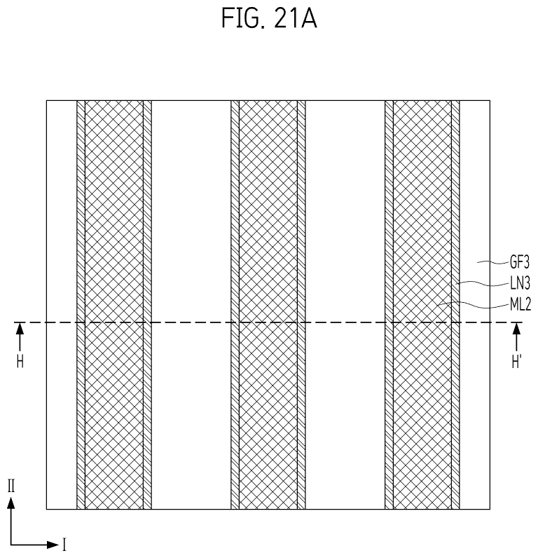

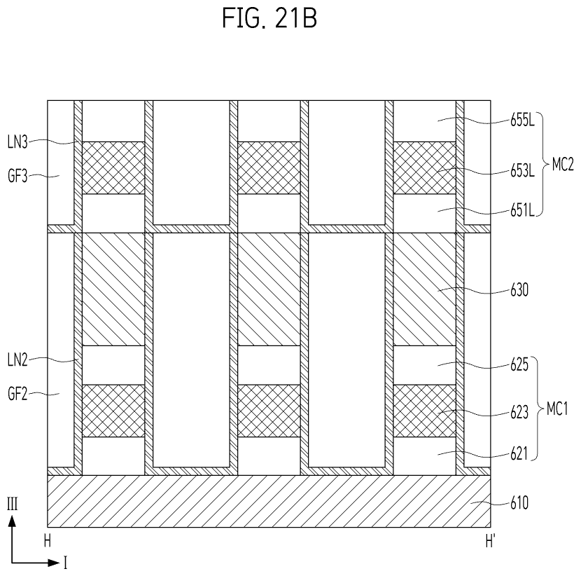

Referring to FIGS. 21A and 21B, second memory lines ML2, third gap-fill patterns GF3, and third liner patterns LN3 may be formed using processes which are the same or similar to those of the method of forming the second memory lines ML2, the third gap-fill patterns GF3, and the third liner patterns LN3 of FIGS. 10A and 10B. Here, the second memory lines ML2 may include second lower electrode lines 651L, second variable resistance lines 653L, and second upper electrode lines 655L.

Referring to FIGS. 22A and 22B, second memory cells MC2, second row lines 660, fourth gap-fill patterns GF4, and fourth liner patterns LN4 may be formed using processes which are the same or similar to those of the method of forming the second memory cells MC2, the second row lines 460, the fourth gap-fill patterns GF4, and the fourth liner patterns LN4 of FIGS. 11A and 11B. Here, the second memory cell MC2 may include a second lower electrode pattern 651, a second variable resistance pattern 653, and a second upper electrode pattern 655.

According to the manufacturing method described above, the common column lines 630 shared by the first memory cells MC1 and the second memory cells MC2 may be formed using a damascene process.

Although embodiments of the present disclosure have been described with reference to the accompanying drawings, this is only for the purpose of providing specific examples of the technical concepts of the present disclosure, and the scope of the present disclosure is not limited to the above-described embodiments. In the scope of the technical concepts of the present disclosure described in the claims, various forms of substitution, modification, and changes of the example embodiments will be possible by those skilled in the art to which the present disclosure belongs, and these variations are withing the scope of the present disclosure.

What is claimed is:

1. A semiconductor device comprising:
first row lines extending in a first direction;
first column lines located over the first row lines and extending in a second direction crossing the first direction;
second column lines located over the first column lines, the second column lines having a width greater than a width of the first column lines and extending in the second direction;
second row lines located over the second column lines and extending in the first direction;
first memory cells located between respective row lines and column lines of the first row lines and the first column lines; and
second liner patterns disposed over sidewalls of the first memory cells and sidewalls of the first column lines that face the first direction.

2. The semiconductor device of claim 1, wherein upper surfaces of the second liner patterns contact lower surfaces of the second column lines.

3. The semiconductor device of claim 1, further comprising:
first liner patterns over sidewalls of the first memory cells that face the second direction,
second memory cells located between respective row lines and column lines of the second column lines and the second row lines;
third liner patterns over sidewalls of the second memory cells that face the first direction; and
fourth liner patterns over sidewalls of the second memory cells that face the second direction.

4. The semiconductor device of claim 3, wherein each of the first memory cells includes a first lower electrode pattern located over a first row line, a first variable resistance pattern located over the first lower electrode pattern, and a first upper electrode pattern located over the first variable resistance pattern, and
each of the second memory cells includes a second lower electrode pattern located over a second column line, a second variable resistance pattern located over the second lower electrode pattern, and a second upper electrode pattern located over the second variable resistance pattern.

5. The semiconductor device of claim 4, wherein each of the first liner patterns extends along the first row line, the first lower electrode pattern, the first variable resistance pattern, and the first upper electrode pattern, and
each of the second liner patterns extends along the first lower electrode pattern, the first variable resistance pattern, the first upper electrode pattern, and the first column line.

6. The semiconductor device of claim 4, wherein each of the third liner patterns extends along the second lower electrode pattern, the second variable resistance pattern, and the second upper electrode pattern, and
each of the fourth liner patterns extends along the second lower electrode pattern, the second variable resistance pattern, the second upper electrode pattern, and the second row line.

7. The semiconductor device of claim 3, further comprising:
first gap-fill patterns located between adjacent memory cells of the first memory cells in the second direction;
second gap-fill patterns located between adjacent memory cells of the first memory cells in the first direction;
third gap-fill patterns located between adjacent memory cells of the second memory cells in the first direction; and
fourth gap-fill patterns located between adjacent memory cells of the second memory cells in the second direction.

8. The semiconductor device of claim 7, wherein upper surfaces of the second gap-fill patterns are located at substantially the same level as upper surfaces of the second column lines.

9. The semiconductor device of claim 7, wherein the first gap-fill patterns have a first height, and
the second gap-fill patterns have a second height greater than the first height.

10. The semiconductor device of claim 7, wherein the third gap-fill patterns have a third height, and
the fourth gap-fill patterns have a fourth height greater than the third height.

11. The semiconductor device of claim 1, wherein the first column lines and the second column lines are common column lines.

12. A method of manufacturing a semiconductor device, the method comprising:
forming first memory lines extending in a first direction;
forming first gap-fill patterns between the first memory lines;
forming a hard mask layer over the first memory lines;
forming hard mask lines extending in a second direction crossing the first direction by etching the hard mask layer;
forming first memory cells arranged in the first direction and the second direction by etching the first memory lines;
forming second gap-fill patterns between adjacent memory cells of the first memory cells in the first direction;
forming trenches by removing the hard mask lines; and
forming a conductive material in the trenches.

13. The method of claim 12, further comprising:
forming the first memory lines over a first conductive layer;
forming first row lines by etching the first conductive layer;
forming a second conductive layer over the first memory lines; and
forming first column lines extending in the second direction by etching the second conductive layer.

14. The method of claim 13, wherein the trenches are formed by removing the hard mask lines so that the first column lines are exposed, and second column lines are formed by forming the conductive material in the trenches.

15. The method of claim 14, further comprising:
forming second memory lines over the second column lines;
forming third gap-fill patterns between the second memory lines;
forming a fourth conductive layer over the second memory lines;
forming second row lines and second memory cells by sequentially etching the fourth conductive layer and the second memory lines; and
forming fourth gap-fill patterns between the second memory cells.

16. The method of claim 15, further comprising:
forming a third liner layer over the second memory lines before forming the third gap-fill patterns; and
forming a fourth liner layer over the second memory cells before forming the fourth gap-fill patterns.

17. The method of claim 13, further comprising:
forming a first liner layer over the first memory lines before forming the first gap-fill patterns; and
forming a second liner layer over the first memory cells before forming the second gap-fill patterns.

18. The method of claim 17, wherein the trenches are formed by removing the hard mask lines and the second liner layer so that the first column lines are exposed.

19. The method of claim 17, wherein the trenches are formed in the second liner layer by selectively removing the hard mask lines so that the first column lines are exposed.

20. The method of claim 17, wherein the second gap-fill patterns include a material having an etching selectivity with respect to the second liner layer and the hard mask layer.

21. The method of claim 20, wherein the second gap-fill patterns include an oxide material, and
the second liner layer and the hard mask layer include a nitride material.

22. The method of claim 17, wherein the second liner layer includes a material having an etching selectivity with respect to the hard mask layer.

23. The method of claim 22, wherein the second liner layer includes a nitride material, and
the hard mask layer includes polysilicon.

24. The method of claim 12, wherein the trenches are formed by removing the hard mask lines so that the first memory cells are exposed, and common column lines are formed by forming the conductive material in the trenches.
